(19) United States
(12) Patent Application Publication
(10) Pub. No.: US 2016/0276175 A1
(43) Pub. Date: Sep. 22, 2016

(54) LEAD FRAME STRUCTURE, METHOD OF MANUFACTURING LEAD FRAME STRUCTURE, AND SEMICONDUCTOR DEVICE

(71) Applicant: KABUSHIKI KAISHA TOSHIBA, Tokyo (JP)

(72) Inventor: Yoshikatsu KOTOKAWA, Yokohama Kanagawa (JP)

(21) Appl. No.: 15/055,001

(22) Filed: Feb. 26, 2016

(30) Foreign Application Priority Data
Mar. 16, 2015 (JP) 2015-052663

(51) Int. Cl. H01L 21/48; H01L 23/00; H01L 23/31; H01L 23/495; H01L 23/373

(52) U.S. Cl. CPC H01L 21/4882; H01L 23/49568; H01L 23/3736; H01L 23/49565; H01L 21/4821; H01L 23/3121; H01L 24/48; H01L 23/49503; H01L 2224/48091

(57) ABSTRACT

A lead frame structure includes a lead frame having a first surface, a second surface opposed to, and facing away from, the first surface, and a first through-hole extending through the lead frame from the first surface to the second surface, and a heat sink having a third surface contacting the second surface, a fourth surface opposed to, and facing away from, the third surface, and a second through-hole extending through the heat sink from the third surface to the fourth surface, and overlying the location of the first through-hole. The material of one of the heat sink and the lead frame extends through a through opening of the other of the heat sink and the lead frame and extends over a portion of the surface of the other of the heat sink and the lead frame on the second or fourth surfaces.

### CROSS-REFERENCE TO RELATED APPLICATION

This application is based upon and claims the benefit of priority from Japanese Patent Application No. 2015-052663 filed Mar. 16, 2015, the entire contents of which are incorporated herein by reference.

### FIELD

Embodiments described herein relate generally to a lead frame structure, a method of manufacturing a lead frame structure, and a semiconductor device.

### BACKGROUND

It is preferable that a semiconductor device such as a semiconductor package has high heat transfer properties so as to achieve high speed, miniaturization, and the like. As a method of increasing the heat transfer properties of the semiconductor device, for example, connecting a heat sink to a lead frame on which a semiconductor chip is mounted is known. For example, in a process of manufacturing the lead frame structure, a through-hole is formed in a portion of the lead frame, and a protrusion (emboss) is formed at a portion of the heat sink by punching or partial blanking and the like. Next, the protrusion formed in the heat sink is inserted into the through-hole in the lead frame, and the protrusion and the through-hole are swaged together. Through the above-described processes, the lead frame and the heat sink are connected to each other.

However, the method of manufacturing the lead frame structure has the following problem. Specifically, bending or distortion (plastic deformation) is likely to occur during the connection between the lead frame and the heat sink. When the bending or distortion occurs in the lead frame structure, a deviation occurs in a height of an inner lead thereof, and thus a bonding wire and the inner lead may not be connected during wire bonding of a lead wire to the inner lead, or a wire to inner lead connection having low connection strength may occur. As described above, in the lead frame structure, it is desired to suppress deformation during wire bonding connection.

### DESCRIPTION OF THE DRAWINGS

FIG. 1 is a schematic plan view illustrating a structure example of a lead frame structure.

FIG. 2 is a schematic cross-sectional view illustrating a structure example of a connection portion.

FIG. 3 is a schematic cross-sectional view illustrating another structure example of the connection portion.

FIG. 4 is a schematic view illustrating an example of a method of manufacturing the lead frame structure.

FIG. 5 is a schematic view illustrating the example of the method of manufacturing the lead frame structure.

FIG. 6 is a schematic view illustrating the example of the method of manufacturing the lead frame structure.

FIG. 7 is a schematic plan view illustrating a structure example of a semiconductor device.

FIG. 8 is a schematic cross-sectional view illustrating the structure example of the semiconductor device.

FIG. 9 is a schematic cross-sectional view illustrating the structure example of the semiconductor device.

### DETAILED DESCRIPTION

An object of exemplary embodiments is to suppress deformation of a lead frame structure during connection thereof to a heat sink.

In general, according to one embodiment, a lead frame structure, including: a lead frame having a first surface, a second surface that is opposite to the first surface, and a first through-hole that passes through the lead frame from the first surface to the second surface; a heat sink having a third surface that comes into contact with the second surface, a fourth surface that is opposite to the third surface, and a second through-hole which passes through the heat sink from the third surface to the fourth surface, and is configured to overlie the first through-hole. A portion of the material of the heat sink extends through the first through hole and over the first surface and the lead frame and the heat sink are connected to each other, or a portion of the lead frame extends through the second through hole and over the fourth surface and the lead frame and the heat sink are connected to each other.

Hereinafter, embodiments will be described with reference to the accompanying drawings. In addition, the drawings are schematic, and for example, a relation between a thickness and planar dimensions, a thickness ratio of respective layers, and the like may be different from actual values in an actual device. In addition, in the respective embodiments, the same reference numeral will be given to substantially the same structural elements, and description thereof will not be repeated where appropriate.

### First Embodiment

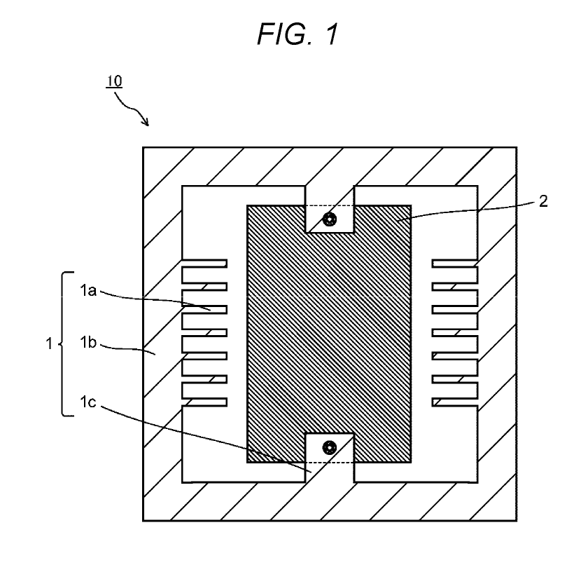

In this embodiment, description will be given of a structure example of a lead frame structure. FIG. 1 is a view illustrating a planar structure example of a lead frame structure 10. The lead frame structure 10 illustrated in FIG. 1 includes a lead frame 1 and a heat sink 2.

The lead frame 1 is a metal sheet on which an element such as a semiconductor chip is mounted. As the lead frame 1 material, copper, a copper alloy, an alloy of iron and nickel such as alloy 42, and the like, may be used.

The lead frame 1 has a first surface (upper surface of the lead frame 1), and a second surface (lower surface of the lead frame 1) opposed to, and facing away from, the first surface. In addition, the lead frame 1 includes a lead portion 1a, a frame portion 1b, and a connection portion 1c. Each of the first surface and the second surface is divided into at least three regions of the lead portion 1a, the frame portion 1b, and the connection portion 1c.

The lead portion 1a is a region that provides leads for the semiconductor device. The lead portion 1a is provided at a peripheral portion of the heat sink 2. In FIG. 1, the lead portion 1a extends from the frame portion 1b toward the heat sink 2, and is separated from the heat sink 2. In FIG. 1, the lead portion 1a is provided only on a left side and on a right side of the heat sink 2. The lead portion 1a may also or alternatively be provided on an upper side and on a lower side of the heat sink 2 in FIG. 1. The individual projections of the lead portion 1a are connected to the semiconductor device by wire bonding wires thereto and to pads on a semiconductor chip mounted to the lead frame 1.

The frame portion 1b is a region that supports the lead portion 1a and the connection portion 1c. In FIG. 1, the frame portion 1b is provided to surround the heat sink 2.

The connection portion 1c extends between the lead frame 1 and the heat sink 2. In FIG. 1, the connection portion 1c extends from the frame portion 1b toward the heat sink 2. In addition, in FIG. 1, although the connection portion 1c is provided on an upper side and on a lower side of the heat sink 2, the configuration is not limited thereto. For example, the connection portion 1c may be provided on a left side and a right side of the heat sink 2.

The heat sink 2 has a third surface (upper surface of the heat sink 2) that comes into contact with the second surface, and a fourth surface (lower surface of the heat sink 2) that is opposed to, and faces away from, to the third surface. The heat sink 2 is stacked on the lead frame 1 so as to overlie the position of at least the connection portion 1c.

The thermal conductivity of the heat sink 2 is higher than the thermal conductivity of the lead frame 1. Accordingly, the heat sink 2 functions as a heat transfer sheet that receives heat generated from the semiconductor chip and the like and transfers that heat out of the package by radiation, conduction and convection. For example, the heat sink 2 includes a metal such as copper. Copper is suitable because copper has high thermal conductivity, and is easy to process. It is preferable that the heat sink 2 has a region that is thicker than the lead frame 1. Accordingly, it is possible to enhance heat transfer properties of the heat sink 2.

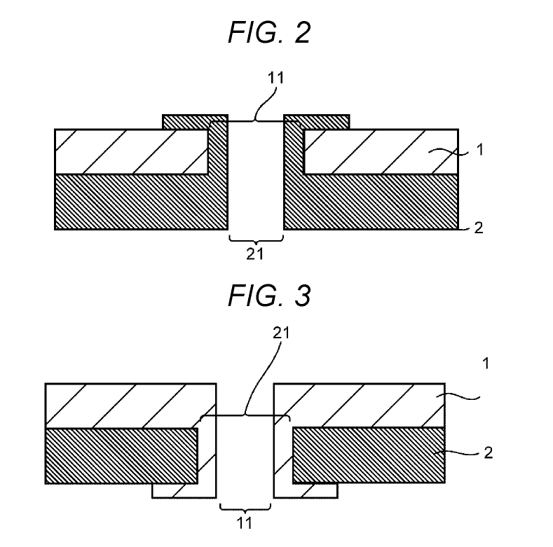

In addition, a structure example of the connection portion 1c will be described with reference to FIG. 2. FIG. 2 is a schematic cross-sectional view illustrating a structure example of a connection portion.

The lead frame structure 10 has a through-hole 11 that passes through the lead frame structure 10 from the first surface to the second surface. The through-hole 11 has a first diameter.

The heat sink 2 has a through-hole 21 that passes through the lead frame structure 10 from the third surface to the fourth surface, and overlies the location of the through-hole 11 in the lead frame structure 10. In FIG. 2, the through-hole 21 has a second diameter that is smaller than the first diameter. Thus, the circumferential peripheral edge of the through-hole 21 extends over the through-hole 11.

The main portion of the heat sink 2 extends along the second surface of the lead frame structure 1, and a portion of the heat sink 2 extends through the through-hole 11 in the lead frame structure 10 and then extends annularly therefrom to overlie and contact the first surface of the lead frame structure 1 adjacent to the through-hole 11, and thus the heat sink 2 is connected to the first surface of the lead frame structure 1 and secured thereto. In FIG. 2, a portion of the heat sink 2 extends along an inner wall of the through-hole 21, and is connected to a peripheral edge of the through-hole 11.

For example, the portion of the heat sink 2 which extends as the connection portion has a so-called eyelet or grommet shape including a cylindrical shape and the like. As described above, the portion of the heat sink 2, which extends through the connection portion 1c has a hollow structure, and thus a volume of the portion of the heat sink 2 extending through the connecting portion 1c is small, and thus it is possible to reduce a residual stress in the lead frame structure 10 as the portion extending through the lead frame 1 can be compressed inwardly of the hollow center.

FIG. 3 is a schematic cross-sectional view illustrating another structure example of the connection portion. As illustrated in FIG. 3, a portion of the lead frame 1e at the through-hole 11 in the second surface extends through the through-hole 21, and over the adjacent portion of the fourth surface of the heat sink 2. In FIG. 3, the second diameter of the through-hole 21 is greater than the first diameter of the through-hole 11. The peripheral edge of the through-hole 11 overlies the through-hole 21. The portion of the lead frame 1 extends to the fourth surface of the heat sink 2 along a side wall of the through-hole 11, and overlies and contacts the peripheral edge of the through-hole 21 at the fourth surface.

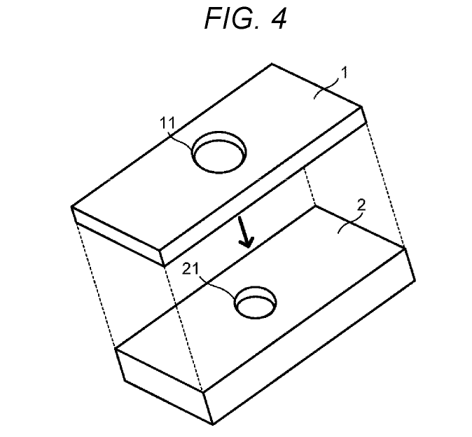

Next, an example of a method of manufacturing the lead frame structure will be described with reference to FIGS. 4 to 6. FIGS. 4 to 6 are schematic views illustrating an example of the method of manufacturing the lead frame structure. In addition, in FIGS. 4 to 6, only partial regions of the lead frame 1 and the heat sink 2 are schematically illustrated for convenience.

As illustrated in FIG. 4, the lead frame 1 and the heat sink 2 are prepared. Next, the lead frame 1 and the heat sink are stacked on each other in such a manner that the through-hole 21 overlies the through-hole 11. In a case where the through-hole 21 diameter is smaller than the through-hole 11 diameter, it is preferable that the lead frame 1 and the heat sink 2 are stacked on each other in such a manner that the peripheral edge of the through-hole 21 extends over the through-hole 11.

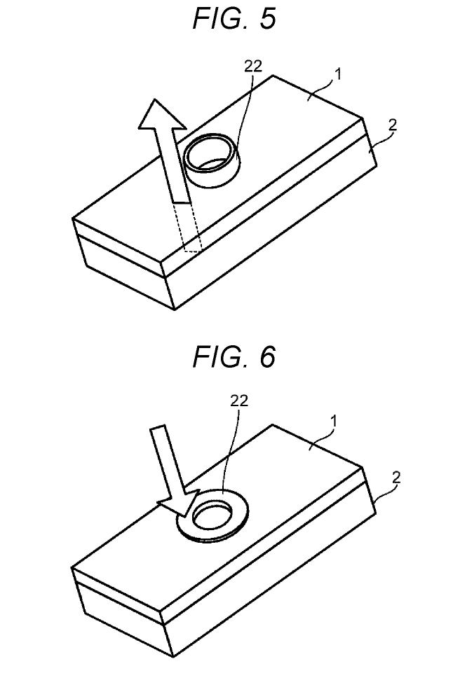

Next, as illustrated in FIG. 5, a portion of the heat sink 2 at the peripheral edge of the through-hole 21 in the third surface is extended through the through-hole 11 until it protrudes from the first surface by, for example, a burring process, thereby forming a protruding portion 22. The burring process is one type of the press-forming process using a punch and a die, and a method of making a hole and a protruding portion at the same time. In the burring process, the portion of the heat sink 2 extending over the through hole 11 is pushed through the through-hole 11 by the punch, stretching the material of the heat sink 2 and extending a portion thereof past the first surface of the lead frame structure 1.

Next, as illustrated in FIG. 6, the portion (protruding portion 22) of the heat sink 2, which protrudes past the first surface of the lead frame structure 1, is connected to the first surface by, for example, curling back the extending end of the protruding portion against the first surface. Curling is a processing method of rolling the protrusion outward over the first surface of the lead frame structure 1. In FIG. 6, the portion (protruding portion 22) of the heat sink 2 which protrudes, is radially spread, and is thus contacted with the peripheral edge of the through-hole 11 at the first surface. It is possible to manufacture the lead frame structure 10 by the above-described processes.

In addition, in a case of the structure illustrated in FIG. 3, the lead frame 1 and the heat sink 2 are stacked on each other in such a manner that the peripheral edge of the through-hole 11 overlaps with the through-hole 21. Next, a portion of the lead frame 1 at the peripheral edge of the through-hole 11 in the second surface is extended by extruding it to protrude through the through-hole 21 from the fourth surface. Next, the portion of the lead frame 1, which protrudes, is connected to the fourth surface by the rolling process. It is possible to manufacture the lead frame structure 10 shown in FIG. 3 by the above-described processes.

When the lead frame structure according to this embodiment is manufactured by the above-described processes, deformation of the lead frame structure during connection of the lead frame structure 1 with the heat sink 2 is suppressed in comparison to a case where the lead frame and the heat sink are connected through, for example, the prior art method described in the background section herein.

In the method of connecting the lead frame and the heat sink using the prior art method, a lead frame having a through-hole, and a heat sink including a protrusion provided using partial-blanking and the like are prepared. Next, the lead frame and the heat sink are stacked on each other in such a manner that the protrusion is inserted into the through-hole. Next, the protrusion is pressed into the opening in the lead frame. Also, the heat sink and lead frame are connected using a swaging method. Accordingly, the connection portion is formed.

In the method of manufacturing the lead frame structure using adhesive, a volume of a portion of the protrusion, which is connected to an upper surface of the lead frame, varies in accordance with a height of the protrusion or positional accuracy of the locations of the protrusion and of the opening in the lead frame. Accordingly, bending or deformation is likely to occur in the lead frame structure. Particularly, the lead frame has a thermal expansion coefficient different from that of the heat sink, and thus the lead frame is likely to be deformed. In addition, if the volume of the protrusion that is formed by partial blanking is great, and thus a residual stress is likely to occur in the lead frame structure.

In contrast, in the lead frame structure according to this embodiment, the peripheral edge of the through-hole (of the lead frame or the heat sink) is extended through the through hole of the adjacent member (the other of the lead frame and heat sink), and thus this protruding portion has a hollow structure. Accordingly, it is possible to make the volume of the heat sink material extending through the lead frame structure 1 be small, as well as somewhat compliant or giving or weaker than, the portion of the lead frame element 1, or vise-versa, and thus it can bend inwardly of the hollow central portion thereof. Accordingly, a load that is applied to the lead frame structure is reduced. As a result, deformation during connection is suppressed, and thus it is possible to enhance the dimensional integrity of the lead frame structure.

### Second Embodiment

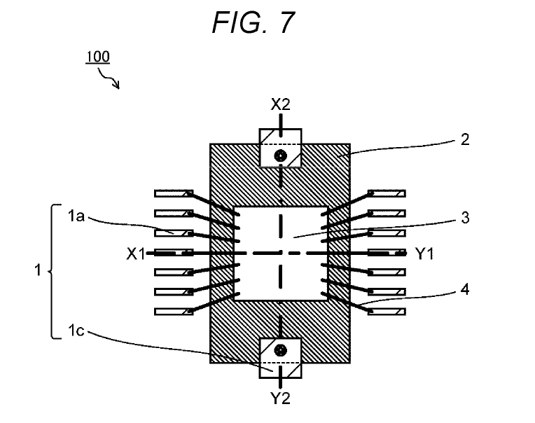

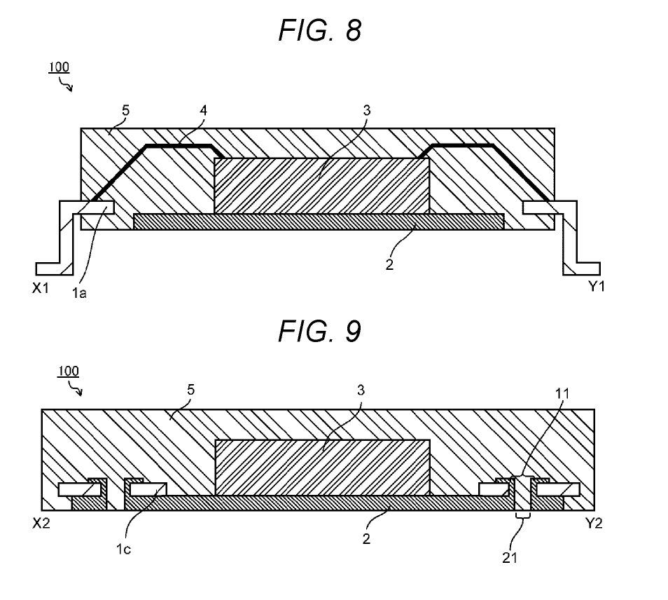

In this embodiment, description will be given of a semiconductor device that uses the lead frame structure according to the first embodiment. FIGS. 7 to 9 are views illustrating a structure example of the semiconductor device using the lead frame structure. FIG. 7 is a schematic plan view, FIG. 8 is a schematic cross-sectional view taken along line segment X1-Y1 in FIG. 7, and FIG. 9 is a schematic cross-sectional view taken along line segment X2-Y2 in FIG. 7.

A semiconductor device 100, which is illustrated in FIGS. 7 to 9, includes a lead frame 1, a heat sink 2, a semiconductor chip 3, a bonding wire 4, and a resin layer 5. In addition, in FIG. 7, the resin layer 5 is omitted for convenience.

The lead frame 1 includes the lead portion 1a and the connection portion 1c in the lead frame 1 illustrated in FIG. 1. In FIG. 7, cutting is performed between the lead portion 1a and the frame portion 1b of the lead frame 1, and between the frame portion 1b and the connection portion 1c, thereby forming the lead frame 1 illustrated in FIG. 7. The other descriptions are the same as in the lead frame structure 10 of the first embodiment, and thus description in the first embodiment may be appropriately referenced.

As the heat sink 2, the heat sink 2 in the first embodiment is applicable. Accordingly, with regard to description of the heat sink 2, description in the first embodiment may be appropriately referenced.

The semiconductor chip 3 is mounted on the third surface of the heat sink 2. The semiconductor chip 3 includes a connection pad on an upper surface thereof. As the semiconductor chip 3, for example, a plurality of the semiconductor chips 3 may be stacked. For stacking, the semiconductor chips 3 may be provided with a penetration electrode such as through silicon via (TSV) extending therethrough. In addition, as the semiconductor chip 3, an external connection terminal such as a bump may be provided.

The bonding wire 4 electrically connects the lead frame 1 and the semiconductor chip 3. In FIG. 7, one end of the bonding wire 4 is connected to the lead portion 1a, and the other end is connected to the connection pad of the semiconductor chip 3.

The resin layer 5 is provided on the first surface, the second surface, and the fourth surface to seal the semiconductor chip 3 and a portion of the heat sink 2 which includes the third surface. For example, the resin layer 5 may be formed in such a manner that a first resin layer is formed to seal the semiconductor chip 3, and a second resin layer is formed to seal a portion of the heat sink 2. Then, the second resin layer is formed in such a manner that at least a portion of the fourth surface is left exposed. In FIG. 9, the through-hole 11 and the through-hole 21 are filled with a portion of the resin layer 5. When the through-hole 11 and the through-hole 21 are filled with the resin layer 5, it is possible to further suppress peeling-off of the resin layer 5 from the lead frame structure 10. In addition, here, the “filling” includes a case where the filling is performed to a portion of the through-hole 11 and the through-hole 21, that is, partway through the through-hole 11 and the through-hole 21 in a depth direction. In addition, in a case where a plurality of the through-holes 11 and the through-holes 21 are formed, the “filling” includes a case where at least portions of some through-holes 11 and through-holes 21 are filled with the resin layer 5. It is enough that the filling with the resin layer 5 is performed to a depth capable of suppressing peeling-off of the resin layer 5 due to an anchoring effect of the resin layer 5 to the through holes 11 and 21 and it is not necessary that the through-holes 11 and the through-holes 21 are completely filled with the resin layer 5 in a depth direction. In addition, it is not necessary for all of the through-holes 11 and through-holes 21 to be filled with the resin layer 5.

The resin layer 5 supports the lead portions 1a, and a portion of the lead portions 1a protrudes from the resin layer 5. A portion of the lead portion 1a, which is supported by the resin layer 5, is referred to as an inner lead, and a portion of the lead portion 1a, which protrudes from the resin layer 5, is referred to as an outer lead. For example, one end of the bonding wire 4 is connected to the inner lead.

The resin layer 5 includes at least inorganic filler such as SiO₂. For example, the resin layer 5 may be configured by using a mixture of the inorganic filler and an organic resin such as an epoxy resin. An amount of the inorganic filler is preferably in a range from 80% to 95% of the entire amount of the mixture. The resin layer 5 is appropriate because the resin layer 5 has high adhesiveness with the lead frame 1.

As described above, when using the lead frame structure in the semiconductor device, it is possible to suppress distortion or bending of the semiconductor chip. In addition, it is possible to provide a semiconductor device having high heat conduction properties therefrom due to the presence of the heat sink.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A lead frame structure, comprising:
a lead frame having a first surface, a second surface opposed to, and facing away from, the first surface, and a first through-hole extending through the lead frame from the first surface to the second surface; and
a heat sink having a third surface contacting the second surface, a fourth surface opposed to, and facing away from, the third surface, and a second through-hole extending through the heat sink from the third surface to the fourth surface, and overlying the location of the first through-hole,
wherein the material of one of the heat sink and the lead frame extends through a through opening of the other of the heat sink and the lead frame and extends over a portion of the surface of the other of the heat sink and the lead frame on the second or fourth surfaces.

2. The structure according to claim 1,
wherein the heat sink includes a region that is thicker than a thickness of the lead frame.

3. The structure according to claim 1,
wherein the heat sink comprises copper.

4. The structure according to claim 1, wherein the portion of the heat sink or lead frame extending through the other of the heat sink or lead frame includes a hollow opening extending therethrough.

5. The structure according to claim 1, wherein the portion of the heat sink or lead frame extending through the other of the heat sink or lead frame is mechanically weaker than the opening through which it extends.

6. The structure according to claim 1, wherein the portion of the lead frame or the heat sink extending through the through opening in the other of the lead frame or the heat sink and the first or the second through-hole through which the portion extends, aligns the heat sink to the lead frame.

7. The structure according to claim 6, further comprising a semiconductor chip mounted to the heat sink at a first side thereof and comprising electrical connections formed on another side thereof, wherein
the lead frame further comprises a plurality of leads, and
the portion of the lead frame or heat sink extending through the through opening in the other of the lead frame or heat sink, and the through hole, align the leads to the electrical connections of the semiconductor chip.

8. A method of manufacturing a lead frame structure, comprising:
providing a lead frame having a first surface, a second surface opposed to the first surface, and a first through-hole extending through the lead frame from the first surface to the second surface thereof;
providing a heat sink having a third surface, a fourth surface opposed to the third surface, and a second through-hole extending through the heat sink from the third surface to the fourth surface;
superimposing the heat sink on the lead frame such that the second through-hole overlies the first through-hole in such a manner that the third surface contacts the second surface; and
extending a first portion of the heat sink at a peripheral edge of the second through-hole in the third surface through the first through-hole until it protrudes from the first surface and thereby connecting the lead frame and the heat sink to each other, or extending a first portion of the lead frame at a peripheral edge of the first through-hole in the second surface through the second through-hole until it protrudes from the fourth surface and thereby connecting the lead frame and the heat sink to each other.

9. The method of claim 8, further comprising extending at least a second portion of the heat sink from the first portion of the heat sink over the first surface.

10. The method of claim 9, wherein the second portion of the heat sink contacts the first surface.

11. The method of claim 8, further comprising extending at least a second portion of the lead frame from the first portion of the lead frame over the fourth surface.

12. The method of claim 11, wherein the second portion of the lead frame contacts the fourth surface.

13. The method of claim 8, further comprising providing a hollow opening extending through the first portion of the heat sink, or through the first portion of the lead frame.

14. The method of claim 8, further comprising locating the first and second through-holes in the lead frame and the heat sink to align the lead frame elements to the heat sink once the lead frame and heat sink are connected.

15. A semiconductor device, comprising:
a lead frame having a first surface, a second surface opposed to the first surface, and a first through-hole extending through the lead frame from the first surface to the second surface;
a heat sink having a third surface contacting the second surface, a fourth surface opposed to the third surface, and a second through-hole extending through the heat sink from the third surface to the fourth surface and overlying the location of the first through-hole;
a semiconductor chip mounted on the third surface; and
a resin layer overlying the semiconductor chip and a portion of the heat sink including the third surface,
wherein at least a portion of the fourth surface is not covered by the resin layer,
wherein a portion of the heat sink protrudes over the first surface from a peripheral edge of the second through-hole at the third surface and through the first through-hole and connects the lead frame and the heat sink, or a portion of the lead frame protrudes over the fourth surface from a peripheral edge of the first through-hole at the second surface and through the second through-hole and connects the lead frame and the heat sink, and
wherein the resin extends inwardly of at least a portion of the first through-hole or the second through-hole.

16. The semiconductor device according to claim 15, wherein
the heat sink includes a chip mounting portion thereon, and
the location of the first through hole through the lead frame and the second through hole through the heat sink align the chip mounting portion to lead elements of the lead frame.

17. The semiconductor device according to claim 15, wherein the heat sink comprises copper.
